(19) United States
(12) Patent Application Publication
(10) Pub. No.: US 2024/0324399 A1
(43) Pub. Date: Sep. 26, 2024

(54) DISPLAY APPARATUS

(71) Applicant: Samsung Display Co., Ltd., Yongin-si (KR)

(72) Inventors: Sungeun Lee, Yongin-si (KR); Jinho Ju, Yongin-si (KR); Jonghyun Choi, Yongin-si (KR)

(73) Assignee: Samsung Display Co., Ltd., Yongin-si (KR)

(21) Appl. No.: 18/403,079

(22) Filed: Jan. 3, 2024

(30) Foreign Application Priority Data
Mar. 24, 2023 (KR) 10-2023-0038991
Apr. 12, 2023 (KR) 10-2023-0048362

(51) Int. Cl. H10K 59/80

(52) U.S. Cl. CPC H10K 59/872

(57) ABSTRACT

A display apparatus includes a first insulating layer disposed on a substate and including an opening filled with an organic material and a first-first insulating portion arranged inside the opening, a second insulating layer disposed on the first insulating layer and including a first-first through-hole filled with the organic material and connected to the opening and a first-second insulating portion arranged inside the first-first through-hole, a third insulating layer disposed on the second insulating layer and including a first-second through-hole filled with the organic material and connected to the first-first through-hole, a target arranged between the first-first insulating portion and the first-second insulating portion and arranged inside the first-first through-hole, and a shield portion disposed on the second insulating layer or the third insulating layer and overlapping the target in a plan view.

### CROSS REFERENCE TO RELATED APPLICATION(S)

This application claims priority to and benefits of Korean Patent Application No. 10-2023-0038991 under 35 U.S.C. § 119, filed on Mar. 24, 2023, and Korean Patent Application No. 10-2023-0048362 under 35 U.S.C. § 119, filed on Apr. 12, 2023, in the Korean Intellectual Property Office (KIPO), the entire contents of which are incorporated herein by reference.

### BACKGROUND

### 1. Technical Field

Embodiments relate to a display apparatus that is more robust against an external impact.

### 2. Description of the Related Art

Display apparatuses display images by receiving information about the images. Display apparatuses are used as displays of small products, such as mobile phones or the like, or as displays of large products, such as televisions or the like.

To display images to the outside, display apparatuses include a plurality of pixels that emit light by receiving electrical signals. Each pixel includes a light-emitting element. For example, organic light-emitting display apparatuses include an organic light-emitting diode as a light-emitting element. In general, organic light-emitting display apparatuses include a thin-film transistor and an organic light-emitting diode formed on a substrate, and the organic light-emitting diode emits light by itself.

Such display apparatuses need to have a structure that is robust against an external impact, for example, damage to internal components due to an external impact.

### SUMMARY

The disclosure provides a display apparatus that is more robust against an external impact. However, such an objective is only an example, and the scope of the disclosure is not limited thereto.

Additional aspects will be set forth in part in the description which follows and, in part, will be apparent from the description, or may be learned by practice of the presented embodiments of the disclosure.

According to an embodiment, a display apparatus may include a first insulating layer disposed on a substrate and including an opening filled with an organic material and a first-first insulating portion arranged inside the opening, a second insulating layer disposed on the first insulating layer and including a first-first through-hole filled with the organic material and connected to the opening and a first-second insulating portion arranged inside the first-first through-hole, a third insulating layer disposed on the second insulating layer and including a first-second through-hole filled with the organic material and connected to the first-first through-hole, a target arranged between the first-first insulating portion and the first-second insulating portion and arranged inside the first-first through-hole, and a shield portion disposed on the second insulating layer or the third insulating layer and overlapping the target in a plan view.

The display apparatus may further include an anti-etching layer arranged between the substrate and the first insulating layer. A lower surface of the opening may include at least a portion of an upper surface of the anti-etching layer.

In a plan view, at least a portion of the target may be covered by the shield portion.

In a plan view, an area of the target may be less than an area of the shield portion.

The display apparatus may further include a first semiconductor layer. The first semiconductor layer and the target may be arranged on a same layer and include a same material.

An inner surface of the opening, an inner surface of the first-first through-hole, and an inner surface of the first-second through-hole may constitute a continuous surface with each other.

A side surface and an upper surface of the target may be covered by the first-second insulating portion.

The display apparatus may further include a first gate layer disposed on the first semiconductor layer and spaced apart from the first semiconductor layer, and a second gate layer disposed on the first gate layer and spaced apart from the first gate layer.

The shield portion and the second gate layer may be arranged on a same layer and may include a same material.

The display apparatus may further include a fourth insulating layer disposed on the third insulating layer and including a first-third through-hole filled with the organic material and connected to the first-second through-hole.

The third insulating layer may include a first-third insulating portion arranged inside the first-second through-hole, and the shield portion may be disposed on the first-third insulating portion and arranged inside the first-third through-hole.

A side surface and an upper surface of the shield portion may be covered by the organic material.

According to an embodiment, a display apparatus may include a first semiconductor layer disposed on a substrate, a first gate insulating layer disposed on the first semiconductor layer, a first gate layer disposed on the first gate insulating layer, a second gate insulating layer disposed on the first gate layer, a second gate layer disposed on the second gate insulating layer, a first interlayer insulating layer disposed on the second gate layer and including an opening filled with an organic material and a second-first insulating portion arranged inside the opening, a third gate insulating layer disposed on the first interlayer insulating layer and including a second-first through-hole filled with the organic material and connected to the opening and a second-second insulating portion arranged inside the second-first through-hole, a second interlayer insulating layer disposed on the third gate insulating layer and including a second-second through-hole filled with the organic material and connected to the second-first through-hole, a target arranged between the second-first insulating portion and the second-second insulating portion and arranged inside the second-first through-hole, and a shield portion disposed on the third gate insulating layer and overlapping the target in a plan view.

The display apparatus may further include an anti-etching layer arranged between the second gate insulating layer and the first interlayer insulating layer. A lower surface of the opening may include at least a portion of an upper surface of the anti-etching layer.

In a plan view, at least a portion of the target may be covered by the shield portion.

In a plan view, an area of the target may be less than an area of the shield portion.

The display apparatus may further include a second semiconductor layer. The second semiconductor and the target may be arranged on a same layer and include a same material.

The second semiconductor layer may include an oxide semiconductor.

An inner surface of the opening, an inner surface of the second-first through-hole, and an inner surface of the second-second through-hole may constitute a continuous surface with each other.

A side surface and an upper surface of the target may be covered by the second-second insulating portion.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display panel of a display apparatus in accordance with an embodiment;

FIG. 2 is a schematic diagram of an equivalent circuit of a pixel included in the display panel of FIG. 1;

FIG. 3 is a schematic cross-sectional view of a portion of the display panel of FIG. 1 in accordance with an embodiment;

FIG. 4 is a schematic cross-sectional view of a middle area of FIG. 3 in accordance with another embodiment;

FIG. 5 is a schematic cross-sectional view of the middle area of FIG. 3 in accordance with another embodiment;

FIG. 6 is a schematic cross-sectional view of the middle area of FIG. 3 in accordance with another embodiment;

FIG. 7 is a schematic cross-sectional view of a portion of the display panel of FIG. 1 in accordance with another embodiment;

FIG. 8 is a schematic cross-sectional view of area A of FIG. 7 in accordance with another embodiment;

FIG. 9 is a schematic cross-sectional view of the area A of FIG. 7 in accordance with another embodiment; and

FIG. 10 is a schematic cross-sectional view of a portion of the display panel of FIG. 1 in accordance with another embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.” Throughout the disclosure, the expression “at least one of a, b, and c” indicates only a, only b, only c, both a and b, both a and c, both b and c, all of a, b, and c, or variations thereof. Also, “at least two of x, y, and z” indicates two or more of x, y, and z such as both x and y, both x and z, both y and z, both x, y, and z.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments of the disclosure will be described in detail with reference to the accompanying drawings. When describing embodiments with reference to the drawings, the same or corresponding elements are denoted by the same reference numerals, and redundant descriptions thereof are omitted.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” “including,” “has,” and/or “having,” when used in this specification, specify the presence of stated features, integers, steps, operations, elements, components, and/or groups thereof, but do not preclude the presence or addition of one or more other features, integers, steps, operations, elements, components, and/or groups thereof.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

In the following embodiments, when an element, such as a layer, a film, a region, or a plate, is referred to as being “on” another element, the element can be directly on the other element or intervening elements may be present therebetween. When, however, an element or layer is referred to as being “directly on” or “directly connected to” another element or layer, there are no intervening elements or layers present. To this end, the term “connected” may refer to physical, electrical, and/or fluid connection, with or without intervening elements.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Spatially relative terms, such as “below,” “lower,” “above,” “upper,” “side,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

In addition, the size and relative sizes of elements in the drawings may be exaggerated for convenience of description. For example, because sizes and thicknesses of elements in the drawings are arbitrarily illustrated for convenience of description, the disclosure is not limited thereto.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. When an embodiment may be implemented differently, a specific process order may be performed differently from the described order. For example, two consecutively described processes may be performed substantially at the same time or performed in an order opposite to the described order.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

In the following embodiments, the x-axis, the y-axis, and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

The display surface may be parallel to a surface defined by an x direction and a y direction. A normal direction of the display surface, i.e., a thickness direction of the display apparatus, may indicate a z direction. In this specification, an expression of “when viewed from the top or in a plan view” may represent a case when viewed in the z direction. Hereinafter, a front surface (or a top surface) and a rear surface (or a bottom surface) of each of layers or units may be distinguished by the z direction.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display apparatus according to an embodiment is described in detail based on the above descriptions.

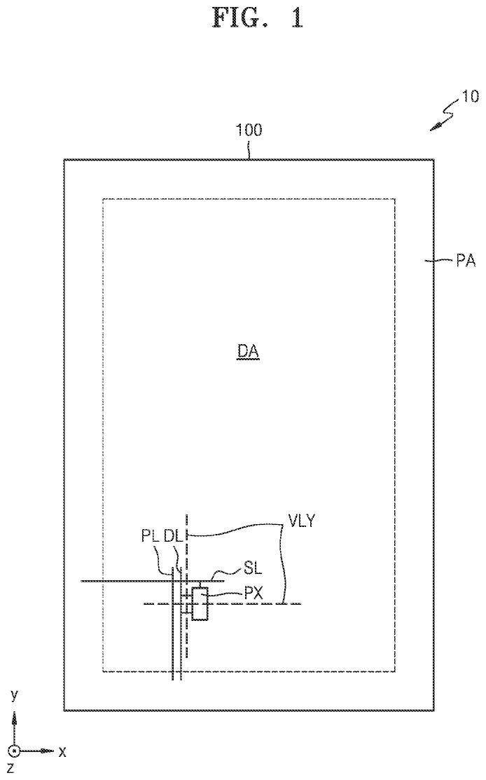

FIG. 1 is a schematic plan view of a display panel 10 of the display apparatus in accordance with an embodiment.

As illustrated in FIG. 1, the display apparatus according to an embodiment may include a display panel 10. The display apparatus may be of any type as long as the display apparatus includes a display panel 10. For example, the display apparatus may be various apparatuses, such as a smartphone, a tablet personal computer, a laptop computer, a television, a billboard, and the like. The display apparatus according to an embodiment may include thin-film transistors, a capacitor, and the like, and the thin-film transistors, the capacitor, and the like may be implemented by conductive layers and insulating layers.

The display panel 10 may include a display area DA and a peripheral area PA arranged adjacent to the display area DA. For example, the peripheral area PA may surround at least a portion of the display area DA. FIG. 1 illustrates that the display area DA has a rectangular shape in a plan view. However, the disclosure is not limited thereto. The display area DA may have various shapes, such as a circular shape, an oval shape, a polygonal shape, a shape of a figure (e.g., a specific figure), and the like.

The display area DA may be an area in which an image is displayed, and multiple pixels PX may be arranged in the display area DA. Each pixel PX may include a display element, such as an organic light-emitting diode or the like. Each pixel PX may emit, for example, red, green, or blue light. The pixel PX may be electrically connected to a pixel circuit including a thin-film transistor, a storage capacitor, and the like. The pixel circuit may be electrically connected to a scan line SL that transmits a scan signal, a data line DL that intersects the scan line SL and transmits a data signal, a driving voltage line PL that supplies a driving voltage, and the like. The scan line SL may extend in an x direction (hereinafter, a second direction), and the data line DL and the driving voltage line PL may extend in a y direction (hereinafter, a first direction). The y direction may intersect the x direction.

The pixel PX may emit light having a luminance corresponding to an electrical signal from the pixel circuit to which the pixel PX is electrically connected. The display area DA may display an image (e.g., a certain or selectable image) through light emitted from the pixel PX. For example, the pixel PX may be defined as an emission area that emits light of one of red, green, and blue colors, as described above.

The peripheral area PA, in which the pixel PX is not arranged, may be an area in which no image is displayed. A power supply wiring for driving the pixel PX, and the like, may be arranged in the peripheral area PA. Multiple pads may be arranged in the peripheral area PA, and a printed circuit board including a driving circuit portion or an integrated circuit (IC) element, such as a driver IC or the like, may be arranged in the peripheral area PA and electrically connected to the pads.

The display panel 10 may include a substrate 100, and the substrate 100 may also include the display area DA and the peripheral area PA. The substrate 100 is described below in detail.

Multiple transistors may be arranged in the display area DA. According to a type (N-type or P-type) and/or operation conditions of a transistor, a first terminal of the transistor may be a source terminal or a drain terminal, and a second terminal of the transistor may be a terminal different from the first terminal. For example, in case that the first terminal is a source electrode, the second terminal may be a drain electrode.

The transistors may include a driving transistor, a data write transistor, a compensation transistor, an initialization transistor, an emission control transistor, and the like. The driving transistor may be electrically connected between the driving voltage line PL and the pixel PX (e.g., an organic light-emitting diode), and the data write transistor may be electrically connected to the data line DL and the driving transistor and may perform a switching operation of transmitting a data signal transmitted through the data line DL.

The compensation transistor may be turned on in response to a scan signal received through the scan line SL and may electrically connect the driving transistor to the pixel PX (e.g., an organic light-emitting diode), thereby compensating for a threshold voltage of the driving transistor.

The initialization transistor may be turned on in response to the scan signal received through the scan line SL and may transmit an initialization voltage to a gate electrode of the driving transistor, thereby initializing the gate electrode of the driving transistor. A scan line electrically connected to the initialization transistor and a scan line electrically connected to the compensation transistor may be separate lines.

The emission control transistor may be turned on in response to an emission control signal received through an emission control line, and as a result, a driving current may flow to the pixel PX (e.g., an organic light-emitting diode).

The pixel PX (e.g., an organic light-emitting diode) may include a pixel electrode (e.g., anode) and a counter electrode (e.g., cathode), and the counter electrode may receive a second power voltage. The pixel PX (e.g., an organic light-emitting diode) may receive a driving current from the driving transistor and display an image by emitting light.

Hereinafter, an organic light-emitting display apparatus is described as an embodiment of the display apparatus. However, the display apparatus of the disclosure is not limited thereto. In another embodiment, the display apparatus of the disclosure may include display apparatuses, such as an inorganic light-emitting display apparatus (or inorganic electroluminescent (EL) display apparatus), a quantum dot light-emitting display apparatus, or the like. For example, an emission layer of a display element included in the display apparatus may include an organic material or an inorganic material. The display apparatus may include an emission layer and quantum dots arranged on a path of light emitted from the emission layer.

A valley structure VLY may be a structure that is filled with an organic material to protect internal components of the display apparatus from an external impact. The valley structure VLY may include through-holes formed in multiple insulating layers, an opening formed in a lowermost insulating layer, and an organic material filled in the through-holes and the opening in a direction intersecting the substrate 100. The organic material may be filled so as to form a columnar shape. As described below, a target described below and multiple insulators arranged adjacent to (or around) the target may be arranged inside the valley structure VLY.

In a plan view, the valley structure VLY may be arranged in the peripheral area PA or in the display area DA. In a plan view, the valley structure VLY may be arranged adjacent to (or around) the pixel PX spaced apart from the pixel PX, or may pass through the pixel PX. Valley structures VLY described herein may be embodiments of the valley structure VLY arranged in the display area DA.

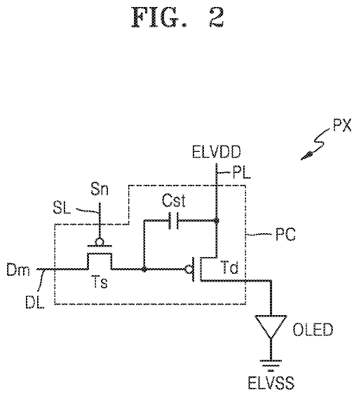

FIG. 2 is a schematic diagram of an equivalent circuit of a pixel PX included in the display panel 10 of FIG. 1.

As illustrated in FIG. 2, each pixel PX may include a pixel circuit PC electrically connected to the scan line SL and the data line DL, and an organic light-emitting diode OLED electrically connected to the pixel circuit PC.

The pixel circuit PC may include a driving thin-film transistor Td, a switching thin-film transistor Ts, and a storage capacitor Cst. The switching thin-film transistor Ts may be electrically connected to the scan line SL and the data line DL and may transmit, in response to a scan signal Sn input through the scan line SL, a data signal Dm input through the data line DL to the driving thin-film transistor Td.

The storage capacitor Cst may be electrically connected to the switching thin-film transistor Ts and the driving voltage line PL and may store a voltage corresponding to a difference between a voltage received from the switching thin-film transistor Ts and a first power voltage ELVDD supplied to the driving voltage line PL.

A second power voltage ELVSS may be a driving voltage having a relatively lower level than the first power voltage ELVDD. A level of a driving voltage supplied to each pixel PX may be a difference between levels of the first power voltage ELVDD and the second power voltage EVLSS.

The driving thin-film transistor Td may be electrically connected to the driving voltage line PL and the storage capacitor Cst and may control a driving current flowing in the organic light-emitting diode OLED through the driving voltage line PL in response to a value of the voltage stored in the storage capacitor Cst. The organic light-emitting diode OLED may emit light having a luminance (e.g., a certain or selectable luminance) due to the driving current.

Although FIG. 2 illustrates that the pixel circuit PC includes two thin-film transistors and one storage capacitor, the disclosure is not limited thereto. The pixel circuit PC may include two or more storage capacitors.

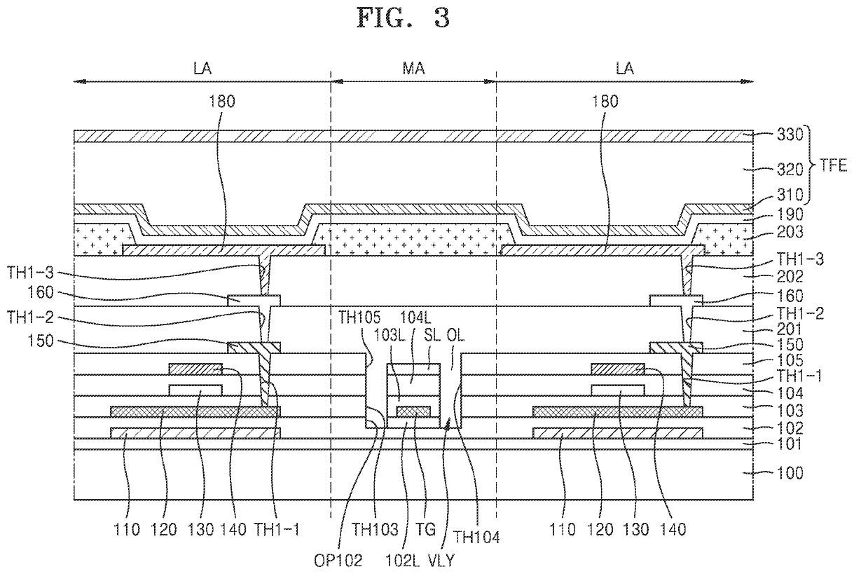

FIG. 3 is a schematic cross-sectional view of a portion of the display panel 10 of FIG. 1 in accordance with an embodiment.

As illustrated in FIG. 3, the portion of the display panel 10 of FIG. 1 may include a middle area MA arranged between pixel electrodes 180 described below, and areas LA arranged on both sides of the middle area MA. Because patterns of repeated shapes are used in patterning for implementing an image in the display panel 10, for convenience of description, an embodiment that structures of the areas LA arranged on both sides of the middle area MA are symmetrical or identical to each other is described. However, the disclosure is not limited thereto, and in another embodiment, the areas LA may have different structures.

In the following descriptions, a stacked structure of areas other than the middle area MA is described.

As described above, the substrate 100 may include areas corresponding to the display area DA and the peripheral area PA arranged adjacent to (or surrounding) the display area DA. The substrate 100 may include a flexible or bendable material. For example, the substrate 100 may include glass, a metal, a polymer resin, or the like. The substrate 100 may include a polymer resin including polyethersulfone, polyacrylate, polyetherimide, polyethylene naphthalate, polyethylene terephthalate, polyphenylene sulfide, polyarylate, polyimide, polycarbonate, cellulose acetate propionate, the like, or a combination thereof.

A barrier layer 101 may be disposed on the substrate 100. The barrier layer 101 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), the like, or a combination thereof. The barrier layer 101 may prevent diffusion of metal atoms or impurities from the substrate 100 toward a semiconductor layer disposed on the substrate 100.

A lower metal layer 110 may be disposed on the substrate 100 or the barrier layer 101. The lower metal layer 110 may include a metal, such as molybdenum (Mo), silver (Ag), copper (Cu), aluminum (Al), the like, or an alloy thereof. The lower metal layer 110 may include a single metal, or may include two or more metals or an alloy of two or more metals. The lower metal layer 110 may have a single layer or multilayer. The lower metal layer 110 may be electrically connected to electrodes through a contact hole or the like. In an embodiment, the lower metal layer 110 may form a capacitor together with another metal layer. The lower metal layer 110 may be disposed below a first semiconductor layer 120 described below and protect the first semiconductor layer 120 from light or the like entering from below the first semiconductor layer 120.

A buffer layer 102 may be disposed on the lower metal layer 110. The buffer layer 102 may prevent diffusion of impurity ions and infiltration of moisture or external air and may serve as a blocking layer for planarizing a surface. The buffer layer 102 may include SiO₂, SiNₓ, SiON, the like, or a combination thereof. The buffer layer 102 may control a heat supply speed during a crystallization process for forming a semiconductor layer described below, so that the semiconductor layer may be uniformly crystallized.

The first semiconductor layer 120 may be disposed on the buffer layer 102. The first semiconductor layer 120 may include polysilicon (in embodiments, SiO₂) and may include a channel area not doped with impurities and a source area and a drain area at each side of the channel area that are doped with impurities. The impurities may vary according to a type of a thin-film transistor and may be N-type impurities or P-type impurities.

For example, during forming of the first semiconductor layer 120, an amorphous silicon layer may be formed on the substrate 100, a polysilicon layer may be formed by irradiating the amorphous silicon layer with an excimer laser beam or the like to crystallize the amorphous silicon layer, and the polysilicon layer may be patterned to form the first semiconductor layer 120. The first semiconductor layer 120 may need to have uniform electrical characteristics with respect to multiple pixels PX so that, in case that the same electrical signal is applied to the multiple pixels PX, light of the same luminance may be emitted from the pixels PX.

A first gate insulating layer 103 may be disposed on the first semiconductor layer 120. The first gate insulating layer 103 may secure insulation between the first semiconductor layer 120 and a first gate layer 130 described below. The first gate insulating layer 103 may include an inorganic material, such as SiO₂, SiNₓ, SiON, the like, or a combination thereof, and may be arranged between the first semiconductor layer 120 and the first gate layer 130 described below. The first gate insulating layer 103 may have a shape corresponding to a surface (e.g., an entire surface) of the substrate 100 and may include a contact hole. The first gate insulating layer 103 may include an inorganic material and may be formed through chemical vapor deposition (CVD), atomic layer deposition (ALD), or the like. This may also apply to embodiments described below and modifications thereof.

The first gate layer 130 may be disposed on the first gate insulating layer 103. The first gate layer 130 may be disposed at a position vertically overlapping the first semiconductor layer 120 and may include a metal such as Mo, Al, platinum (Pt), palladium (Pd), Ag, magnesium (Mg), gold (Au), nickel (Ni), neodymium (Nd), iridium (Ir), chromium (Cr), lithium (Li), calcium (Ca), titanium (Ti), tungsten (W), Cu, and a combination thereof. The first gate layer 130 may be spaced apart from the first semiconductor layer 120 in a thickness direction of the display apparatus.

At least a portion of the first gate layer 130 may overlap the first semiconductor layer 120 in a plan view. Conversely, at least a portion of the first semiconductor layer 120 may overlap the first gate layer 130 in a plan view.

The second gate insulating layer 104 may be disposed on the first gate layer 130. The second gate insulating layer 104 may secure insulation between the first gate layer 130 and a second gate layer 140 described below. The second gate insulating layer 104 may include an inorganic material, such as SiO₂, SiNₓ, SiON, the like, or a combination thereof, and may be arranged between the first gate layer 130 and the second gate layer 140 described below. The second gate insulating layer 104 may have a shape corresponding to the surface (e.g., the entire surface) of the substrate 100 and may include a contact hole. The second gate insulating layer 104 may include an inorganic material and may be formed through CVD, ALD, or the like. This may also apply to embodiments described below and modifications thereof.

The second gate layer 140 may be disposed on the second gate insulating layer 104. The second gate layer 140 may be disposed at a position vertically overlapping the first gate layer 130 and may include a metal such as Mo, Al, Pt, Pd, Ag, Mg, Au, Ni, Nd, Ir, Cr, Li, Ca, Ti, W, Cu, and a combination thereof.

At least a portion of the second gate layer 140 may overlap the first gate layer 130 in a plan view. Conversely, at least a portion of the first gate layer 130 may overlap the second gate layer 140 in a plan view. The 140 may be spaced apart from the first gate layer 130 in the thickness direction.

A first interlayer insulating layer 105 may be disposed on the second gate layer 140. The first interlayer insulating layer 105 may cover the second gate layer 140. The first interlayer insulating layer 105 may include an inorganic material. For example, the first interlayer insulating layer 105 may include a metal oxide or a metal nitride. For example, the first interlayer insulating layer 105 may include SiO₂, SiNₓ, SiON, Al₂O₃, TiO₂, Ta₂O₅, HfO₂, ZnO₂, the like, or a combination thereof. In embodiments, the first interlayer insulating layer 105 may have a dual structure, such as SiOₓ/SiN_{y}, SiNₓ/SiO_{y}, or the like.

A first conductive layer 150 may be disposed on the first interlayer insulating layer 105. The first conductive layer 150 may serve as an electrode electrically connected to the source or drain area of the first semiconductor layer 120 through a first-first contact hole TH1-1 included in the first interlayer insulating layer 105. The first conductive layer 150 may include a metal such as Al, Pt, Pd, Ag, Mg, Au, Ni, Nd, Ir, Cr, Li, Ca, Mo, Ti, W, Cu, and a combination thereof. For example, the first conductive layer 150 may include a Ti layer, an Al layer, a Cu layer, the like, or a combination thereof.

A first organic insulating layer 201 may be disposed on the first conductive layer 150. The first organic insulating layer 201, which covers an upper surface of the first conductive layer 150 and has an approximately flat upper surface, may be an organic insulating layer serving as a planarization layer. The first organic insulating layer 201 may include, for example, an organic material, such as an acryl material, benzocyclobutene (BCB), hexamethyldisiloxane (HMDSO), or the like. The first organic insulating layer 201 may have a single layer or multilayer and may be variously modified.

A second conductive layer 160 may be disposed on the first organic insulating layer 201. The second conductive layer 160 may serve as an electrode electrically connected to the source or drain area of the first semiconductor layer 120 through a first-second contact hole TH1-2 included in the first organic insulating layer 201. The second conductive layer 160 may include a metal such as Al, Pt, Pd, Ag, Mg, Au, Ni, Nd, Ir, Cr, Li, Ca, Mo, Ti, W, Cu, and a combination thereof. For example, the second conductive layer 160 may include a Ti layer, an Al layer, a Cu layer, the like, or a combination thereof.

A second organic insulating layer 202 may be disposed on the second conductive layer 160. The second organic insulating layer 202, which covers an upper surface of the second conductive layer 160 and has an approximately flat upper surface, may be an organic insulating layer serving as a planarization layer. The second organic insulating layer 202 may include, for example, an organic material, such as an acrylic material, BCB, HMDSO, or the like. The second organic insulating layer 202 may have a single layer or multilayer and may be variously modified.

Although not illustrated in FIG. 3, an additional conductive layer and an additional insulating layer may be arranged between a conductive layer (e.g., the first conductive layer 150, the second conductive layer 160) described above and the pixel electrode 180 described below. The additional conductive layer and the conductive layer described above may include a same material, and have a same layer structure. The additional insulating layer and the organic insulating layer described above (e.g., the first organic insulating layer 201, the second organic insulating layer 202) may include a same material, and have a same layer structure.

The pixel electrode 180 may be disposed on the second organic insulating layer 202. The pixel electrode 180 may be electrically connected to the second conductive layer 160 through a first-third contact hole TH1-3 formed in the second organic insulating layer 202. A display element may be disposed on the pixel electrode 180. An organic light-emitting diode may be used as the display element. For example, the organic light-emitting diode may be disposed, on the pixel electrode 180. The pixel electrode 180 may include a transmissive conductive layer including a transmissive conductive oxide, such as indium tin oxide (ITO), indium oxide (In₂O₃), indium zinc oxide (IZO), the like, or a combination thereof, and a reflective layer including a metal, such as Al, Ag, the like, or an alloy thereof. For example, the pixel electrode 180 may have a three-layer structure of ITO/Ag/ITO.

A pixel-defining layer 203 may be disposed on the second organic insulating layer 202 and may cover an edge of the pixel electrode 180. For example, the pixel-defining layer 203 may cover the edge of the pixel electrode 180. The pixel-defining layer 203 may have an opening corresponding to the pixel PX, and the opening may expose at least a portion (e.g., a central portion) of the pixel electrode 180. The pixel-defining layer 203 may include an organic material, such as polyimide, HMDSO, the like, or a combination thereof.

An intermediate layer (not illustrated) and a counter electrode 190 may be disposed on the opening of the pixel-defining layer 203. The intermediate layer (not illustrated) may include a low-molecular weight material, a polymer material, or the like. In case that the intermediate layer (not illustrated) includes a low-molecular weight material, the intermediate layer (not illustrated) may include a hole injection layer, a hole transport layer, an emission layer, an electron transport layer, and/or an electron injection layer. In case that the intermediate layer (not illustrated) includes a polymer material, the intermediate layer (not illustrated) may generally have a structure including a hole transport layer and an emission layer.

The counter electrode 190 may include a transmissive conductive layer including a transmissive conductive oxide, such as ITO, In₂O₃, IZO, the like, or a combination thereof. The pixel electrode 180 may be used as an anode, and the counter electrode 190 may be used as a cathode. In another embodiment, the above polarities of the electrodes may be reversely applied.

A structure of the intermediate layer (not illustrated) is not limited to the above descriptions and may include various structures. For example, at least one of the layers constituting the intermediate layer (not illustrated) may be integrally formed as a single body with the counter electrode 190. In another embodiment, the intermediate layer (not illustrated) may include a layer patterned to correspond to each of multiple pixel electrodes 180.

The counter electrode 190 may be arranged in the display area DA on a surface (e.g., an entire surface) of the display area DA. For example, the counter electrode 190 may be integrally formed as a single body and cover multiple pixels PX. The counter electrode 190 may electrically contact a common power supply line (not illustrated) arranged in the peripheral area PA. In an embodiment, the counter electrode 190 may extend to a blocking wall (not illustrated). A thin-film encapsulation layer TFE may cover (entirely cover) the display area DA and extend toward the peripheral area PA to cover at least a portion of the peripheral area PA.

The thin-film encapsulation layer TFE may extend to an outside of the common power supply line (not illustrated). The thin-film encapsulation layer TFE may include a first inorganic encapsulation layer 310, a second inorganic encapsulation layer 330, and an organic encapsulation layer 320 arranged between the first inorganic encapsulation layer 310 and the second inorganic encapsulation layer 330. The first inorganic encapsulation layer 310 and the second inorganic encapsulation layer 330 may each include an inorganic material such as Al₂O₃, TiO₂, Ta₂O₅, HfO₂, ZnO₂, SiO₂, SiNx, SiON, and a combination thereof.

The first inorganic encapsulation layer 310 and the second inorganic encapsulation layer 330 may each have a single layer or multilayer. The first inorganic encapsulation layer 310 and the second inorganic encapsulation layer 330 may include a same material or different materials. The first inorganic encapsulation layer 310 and the second inorganic encapsulation layer 330 may have different thicknesses. A thickness of the first inorganic encapsulation layer 310 may be greater than a thickness of the second inorganic encapsulation layer 330. In another embodiment, the thickness of the second inorganic encapsulation layer 330 may be greater than the thickness of the first inorganic encapsulation layer 310, or the first inorganic encapsulation layer 310 and the second inorganic encapsulation layer 330 may have a same thickness.

The organic encapsulation layer 320 may include a monomer-based material, a polymer-based material, or the like. For example, the organic encapsulation layer 320 may include an acrylic resin, an epoxy-based resin, polyimide, polyethylene, the like, or a combination thereof. In an embodiment, the organic encapsulation layer 320 may include acrylate.

In the following descriptions, a stacked structure in the middle area MA is described. The middle area MA, in which the valley structure VLY is formed, may be a space arranged between the pixel electrodes 180 in a plan view. For convenience of description, the valley structure VLY is described as being formed in the middle area MA, but the disclosure is not limited thereto, and in another embodiment, the valley structure VLY may be formed below the pixel electrode 180.

The valley structure VLY may be a structure including a column including an organic material OL filled in an area that is dug in a shape of a valley. For example, the valley structure VLY may be defined by through-holes each formed in multiple insulating layers, an opening included in a lowermost insulating layer, and the organic material OL filled in the through-holes and the opening. The valley structure VLY may be variously modified and used according to a combination of through-holes each formed in multiple insulating layers and an opening included in a lowermost insulating layer. The term “valley structure VLY” may be defined as a configuration that absorbs an external impact by using the organic material OL filled in the direction intersecting the substrate 100.

In case that the valley structure VLY is applied to the display apparatus or display panel 10, even in case that an external impact is applied to the display apparatus or display panel 10, the external impact may be dispersed by a column structure, including the organic material OL, of the valley structure VLY. The valley structure VLY may be formed in the peripheral area PA of FIG. 1, but the disclosure is not limited thereto, and in another embodiment, the valley structure VLY may be formed in the display area DA of FIG. 1.

The display panel 10 of FIG. 1 in the middle area MA may include the substrate 100, a first insulating layer, a second insulating layer, a third insulating layer, a target, and a shield portion (see, e.g., SL in FIG. 3).

The first insulating layer may be disposed on the substrate 100 and may include an opening filled with the organic material OL. In FIG. 3, the first insulating layer may be the buffer layer 102. However, the disclosure is not limited thereto, and in another embodiment, the first insulating layer may be the barrier layer 101, the first gate insulating layer 103, the second gate insulating layer 104, or the like.

For example, the first insulating layer may be disposed on an anti-etching layer described below and may be one of insulating layers of the barrier layer 101, the buffer layer 102, the first gate insulating layer 103, the second gate insulating layer 104, the first interlayer insulating layer 105, and the like. The first insulating layer, which is a layer including an opening in the valley structure VLY formed in the middle area MA, may be a layer covering an edge of an insulating layer or anti-etching layer arranged at a lowermost level in the valley structure VLY.

According to an embodiment illustrated in FIG. 3, the first insulating layer may be the buffer layer 102, the second insulating layer may be the first gate insulating layer 103, and the third insulating layer may be the second gate insulating layer 104. Definitions of the first insulating layer, the second insulating layer, and the third insulating layer may be changed according to embodiments.

Likewise, according to an embodiment illustrated in FIG. 3, a first-first insulating portion 102L and the buffer layer 102 may be arranged on a same layer, a first-second insulating portion 103L and the first gate insulating layer 103 may be arranged on a same layer, a first-third insulating portion 104L and the second gate insulating layer 104 may be arranged on a same layer, and a target TG and the first semiconductor layer 120 may be arranged on a same layer. A shield portion SL and the second gate layer 140 may be arranged on a same layer.

Likewise, according to an embodiment illustrated in FIG. 3, an opening OP102 may be included in the buffer layer 102 and open upward, a first-first through-hole TH103 may be included in the first gate insulating layer 103 and may pass through the first gate insulating layer 103, a first-second through-hole TH104 may be included in the second gate insulating layer 104 and may pass through the second gate insulating layer 104, and a first-third through-hole TH105 may be included in the first interlayer insulating layer 105 and pass through the first interlayer insulating layer 105.

The first insulating layer may include the opening OP102 filled with the organic material OL, and the first-first insulating portion 102L may be arranged inside the opening OP102. The first-first insulating portion 102L and the first insulating layer may be arranged on a same layer, and may include a same material. The first-first insulating portion 102L and the first insulating layer may have a same layer structure. For example, the first-first insulating portion 102L may be a portion (e.g., a central portion) remaining after an edge of the first insulating layer is etched by an etching process applied to the first insulating layer. In a plan view, a shape of the first-first insulating portion 102L may correspond to a shape of the shield portion SL described below. For example, in a plan view, the shape of the first-first insulating portion 102L and the shape of the shield portion SL may be substantially the same.

The second insulating layer may be disposed on the first insulating layer and may include the first-first through-hole TH103 filled with the organic material OL. The organic material OL filled in the first-first through-hole TH103 and the organic material OL filled in the opening OP102 included in the first insulating layer may be a same organic material.

For example, the second insulating layer may be disposed on a layer corresponding to the first insulating layer, among insulating layers such as the barrier layer 101, the buffer layer 102, the first gate insulating layer 103, the second gate insulating layer 104, and the first interlayer insulating layer 105. The second insulating layer, which is a layer including the first-first through-hole TH103 connected to an opening in the valley structure VLY formed in the middle area MA, may be disposed on the first insulating layer arranged at the lowermost level in the valley structure VLY.

The first-first through-hole TH103 may be connected to the opening OP102 of the first insulating layer. For example, an inner surface of the first-first through-hole TH103 may form (or constitute) a continuous surface with an inner surface of the opening OP102 of the first insulating layer. The first-second insulating portion 103L may be arranged inside the first-first through-hole TH103. The first-second insulating portion 103L and the second insulating layer may be arranged on a same layer, and may include a same material. The first-second insulating portion 103L and the second insulating layer may have a same layer structure.

For example, the first-second insulating portion 103L may be a portion (e.g., a central portion) remaining after an edge of the second insulating layer is etched by an etching process applied to the second insulating layer. In a plan view, a shape of the first-second insulating portion 103L may correspond to the shape of the shield portion SL described below. For example, in a plan view, the shape of the first-second insulating portion 103L and the shape of the shield portion SL described below may be substantially the same.

The first-second insulating portion 103L may be disposed on the first-first insulating portion 102L. A portion of a lower surface of the first-second insulating portion 103L may contact (e.g., directly contact) at least a portion of an upper surface of the first-first insulating portion 102L. The target TG may be arranged between the first-first insulating portion 102L and the first-second insulating portion 103L. The target TG is described below.

The third insulating layer may be disposed on the second insulating layer and may include the first-second through-hole TH104 filled with the organic material OL. The first-second through-hole TH104 may be connected to the first-first through-hole TH103. An inner surface of the first-second through-hole TH104 may form (or constitute) a continuous surface with the inner surface of the first-first through-hole TH103. Accordingly, the inner surface of the opening OP102, the inner surface of the first-first through-hole TH103, and the inner surface of the first-second through-hole TH104 may form (or constitute) a continuous surface with each other.

The first-second through-hole TH104 may be connected to the first-first through-hole TH103 of the second insulating layer and the opening OP102 of the first insulating layer. The first-third insulating portion 104L may be arranged inside the first-second through-hole TH104. The first-third insulating portion 104L and the third insulating layer may be arranged on a same layer, and may include a same material. The first-third insulating portion 104L and the third insulating layer may have a same layer structure. The first-third insulating portion 104L may be formed simultaneously with the third insulating layer.

For example, the first-third insulating portion 104L may be a portion (e.g., a central portion) remaining after an edge of the third insulating layer is etched by an etching process applied to the third insulating layer. In a plan view, a shape of the first-third insulating portion 104L may correspond to the shape of the shield portion SL described below. For example, in a plan view, the shape of the first-third insulating portion 104L and the shape of the shield portion SL described below may be substantially the same. The first-third insulating portion 104L may be disposed on the first-second insulating portion 103L. A lower surface of the first-third insulating portion 104L may contact (e.g., directly contact) an upper surface of the first-second insulating portion 103L. In another embodiment, the first-third insulating portion 104L may be omitted.

The target TG may be arranged between the first insulating layer and the second insulating layer. For example, the target TG may be arranged inside the valley structure VLY, may be disposed on the first-first insulating portion 102L, and may be covered by the first-second insulating portion 103L. Side and upper surfaces of the target TG may be covered by the first-second insulating portion 103L.

The target TG described herein, which is a layer arranged inside the valley structure VLY, may be a layer that performs a function (e.g., a specific function) in the display apparatus or display panel 10, such as a wiring or the like. Accordingly, in case that the target TG is damaged in an etching process for forming the valley structure VLY, an image quality of the display apparatus or display panel 10 may be adversely affected. Accordingly, the target TG may need to be protected from an etching gas used in the etching process. For example, the shield portion SL described below may be disposed on the target TG.

For convenience of description, it may be assumed that an etching process described herein is a dry etching process using an etching gas. However, in another embodiment, the etching process described herein may be a wet etching process, and the etching gas may be replaced with an etching solution.

For example, the target TG and the first semiconductor layer 120 may be arranged on a same layer, and may include a same material. The target TG may be a portion of the first semiconductor layer 120 that is formed by dopant implantation or the like and serve as a wiring.

The shield portion SL for protecting the target TG from an etching gas may be disposed on the target TG. For example, the shield portion SL may be disposed on the first-second insulating portion 103L covering the target TG. In a plan view, the shield portion SL may cover the target TG. For example, in a plan view, an area of the shield portion SL may be greater than an area of the target TG, and the shield portion SL may protect the target TG from an etching gas. Accordingly, a material included in the shield portion SL may be a material having a lower etching rate than a material to be etched (see, e.g., the target TG or the insulating layers described above (e.g., the buffer layer 102, the first gate insulating layer 103, the second gate insulating layer 104, the first interlayer insulating layer 105) in FIG. 3).

In an embodiment, the shield portion SL and the first gate may be arranged on a same layer, and may include ta same material. In another embodiment, the shield portion SL and the second gate layer 140 may be arranged on a same layer and include a same material. The shield portion SL may be formed simultaneously with the first gate layer 130 or the second gate layer 140.

As illustrated in FIG. 3, the target TG and the first semiconductor layer may be arranged on the same layer and formed simultaneously. The shield portion SL may be disposed on the target TG and may be formed simultaneously with the first gate layer 130 or the second gate layer 140 including a metal material to have a low etching rate (e.g., a relatively low etching rate).

For example, the shield portion SL and the second gate layer 140 may be arranged on a same layer, and may include a same material. The shield portion SL may be formed simultaneously with the second gate layer 140 and may be a portion of the second gate layer 140. The shield portion SL may be disposed on the first-first insulating portion 102L and the first-second insulating portion 103L. Because the first interlayer insulating layer 105 is arranged between the first gate layer 130 and the second gate layer 140, the first-third insulating portion 104L may be arranged between the shield portion SL and the first-second insulating portion 103L. The first-third insulating portion 104L and the first interlayer insulating layer 105 may be arranged on a same layer, and may include a same material. The first-third insulating portion 104L and the first interlayer insulating layer 105 may have a same layer structure.

For example, in a plan view, the shield portion SL may cover the first-first to first-third insulating portions 102L, 103L, and 104L. The shield portion SL may cover an upper surface of the first-third insulating portion 104L and may contact (e.g., directly contact) the upper surface of the first-third insulating portion 104L. For example, the shield portion SL may prevent the first-first to first-third insulating portions 102L, 103L, and 104L and the target TG from being etched.

A fourth insulating layer may be disposed on the third insulating layer and may include the first-third through-hole TH105 filled with the organic material OL. The first-third through-hole TH105 may be connected to the first-second through-hole TH104. An inner surface of the first-third through-hole TH105 may form (or constitute) a continuous surface with the inner surface of the first-second through-hole TH104. Accordingly, the inner surface of the opening OP102, the inner surface of the first-first through-hole TH103, the inner surface of the first-second through-hole TH104, and the inner surface of the first-third through-hole TH105 may form (or constitute) a continuous surface with each other.

As illustrated in FIG. 3, the opening OP102 and the first-first to first-third through-holes TH103, TH104, and TH105 may be filled with the organic material OL. The organic material OL may surround side surfaces of the first-first to first-third insulating portions 102L, 103L, and 104L and may cover a side surface of the shield portion SL and an upper surface of the shield portion SL. For example, the organic material OL may be arranged inside the opening OP102 and the first-first to first-third through-holes TH103, TH104, and TH105. Because the height of the shield portion SL is less than the height of the first-third through-hole TH105, the organic material OL filling the first-third through-hole TH105 may cover the outer and upper surfaces of the shield portion SL.

The organic material OL included in the valley structure VLY and arranged inside the opening OP102 and the first-first to first-third through-holes TH103, TH104, and TH105 and a material included in the first organic insulating layer 201 may be a same material. In another embodiment, the organic material OL included in the valley structure VLY and arranged inside the opening OP102 and the first-first to first-third through-holes TH103, TH104, and TH105 and a material included in the first organic insulating layer 201 may be different.

Openings (see, e.g., OP102 of FIG. 3) or through-holes (see, the first-first through-hole TH103, the first-second through-hole TH104, the first-third through-hole TH105) for forming the valley structure VLY may be formed in the inorganic insulating layers (e.g., the first to third insulating layers), and the first organic insulating layer 201 may be formed on the inorganic insulating layers. In another embodiment, as the first organic insulating layer 201 is formed, the organic material OL of the first organic insulating layer 201 may be filled in the valley structure VLY (e.g., an opening or through-holes) that has been formed in advance.

As illustrated in FIG. 3, the valley structure VLY may have a first depth from an upper surface of the first interlayer insulating layer 105 to a bottom surface of the opening OP102 included in the first insulating layer. The valley structure VLY may have a second depth from the upper surface of the first interlayer insulating layer 105 to the upper surface of the shield portion SL. The first depth may be greater than the second depth. Accordingly, buffering against an external impact may be achieved by a portion of the valley structure VLY having the first depth. Accordingly, the valley structure VLY described herein may not only have a buffering effect against an external impact, but also may protect the target TG serving as a wiring or the like from an etching process. Accordingly, the valley structure VLY described herein may be freely arranged within the display area DA of the display apparatus and may provide a greater degree of freedom in designing a display circuit structure including the valley structure VLY.

Furthermore, the valley structure VLY described herein may also have a buffering effect against an external impact by an organic material having the second depth, thereby protecting the target TG from the external impact.

A process for forming a display apparatus or display panel 10 including the valley structure VLY as illustrated in FIG. 3 (hereinafter, a manufacturing method) may be as follows.

The manufacturing method may include forming the buffer layer 102 on the substrate 100. The forming of the buffer layer 102 on the substrate 100 may be performed through CVD, ALD, or the like, or may be performed through another method.

The forming of the buffer layer 102 on the substrate 100 may include forming the barrier layer 101 on the substrate 100, forming the lower metal layer 110 on the barrier layer 101, and forming the buffer layer 102 on the lower metal layer 110.

The forming of the barrier layer 101 may be performed through a method such as CVD, ALD, or the like, or may be performed through another method.

The forming of the lower metal layer 110 on the barrier layer 101 may include an etching process using a mask having a pattern of a shape (e.g., a preset shape). The forming of the lower metal layer 110 on the barrier layer 101 may include forming a metal layer by using a metal, such as Mo, Ag, Cu, Al, the like, or an alloy thereof, through a method such as CVD, ALD, or the like and applying, to the formed metal layer, an etching process using a mask having a pattern of a shape (e.g., a preset shape).

The forming of the buffer layer 102 on the lower metal layer 110 may include forming the buffer layer 102 on the lower metal layer 110 that has been patterned through the etching process and may be a planarization process performed before forming the first semiconductor layer 120.

The manufacturing method may include, after forming the buffer layer 102 on the substrate 100, sequentially forming the first semiconductor layer 120, the first gate insulating layer 103, the first gate layer 130, the second gate insulating layer 104, the second gate layer 140, and the first interlayer insulating layer 105.

In the forming of the first semiconductor layer 120, the first gate insulating layer 103, the first gate layer 130, the second gate insulating layer 104, the second gate layer 140, and the first interlayer insulating layer 105, the forming of the first semiconductor layer 120, the forming of the first gate layer 130, and the forming of the second gate layer 140 may include forming a layer through a method such as CVD, ALD, or the like and applying, to the formed layer, an etching process using a mask having a pattern of a shape (e.g., a preset shape). The forming of the first semiconductor layer 120, the first gate insulating layer 103, the first gate layer 130, the second gate insulating layer 104, the second gate layer 140, and the first interlayer insulating layer 105 may be performed through a method.

The manufacturing method may include, after sequentially forming the first semiconductor layer 120, the first gate insulating layer 103, the first gate layer 130, the second gate insulating layer 104, the second gate layer 140, and the first interlayer insulating layer 105, forming the valley structure VLY by applying an etching process to an area (e.g., a preset area). The forming of the valley structure VLY may include, for example, forming the valley structure VLY in the middle area MA of FIG. 3.

The area for the forming of the valley structure VLY may be defined around an area in which the shield portion SL is arranged in the middle area MA. For example, the area for the forming of the valley structure VLY may include the area in which the shield portion SL is arranged in the middle area MA, in a plan view.

Accordingly, the forming of the valley structure VLY may include removing an insulating material disposed on the shield portion SL in the area in which the shield portion SL is arranged and removing the insulating material to a depth (e.g., a preset depth) in a remaining area in which the shield portion SL is not arranged. For example, as illustrated in FIG. 3, the valley structure VLY may extend to the buffer layer 102. As a result, the valley structure VLY may have the first depth from the upper surface of the first interlayer insulating layer 105 to the bottom surface of the opening OP102 included in the buffer layer 102 and may have the second depth from the upper surface of the first interlayer insulating layer 105 to the upper surface of the shield portion SL. As described above, the first depth may be greater than the second depth.

An etching process used (or included) in the forming of the valley structure VLY and an etching process used in the forming of the first-first contact hole TH1-1 may be the same. As described above, the first-first contact hole TH1-1 may electrically connect the first conductive layer 150 to the first semiconductor layer 120.

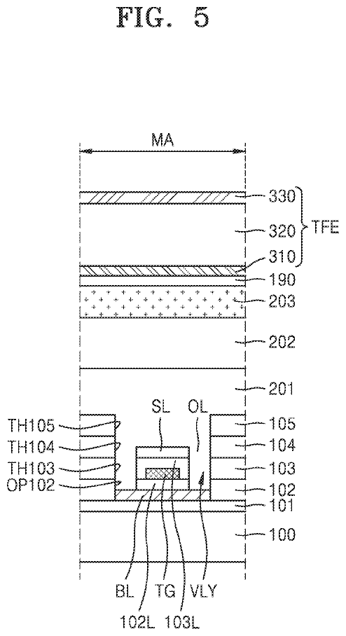

In case that the display panel 10 includes an anti-etching layer BL as illustrated in FIG. 5 described below, the forming of the valley structure VLY may include removing the insulating material up to an upper surface of the anti-etching layer BL. As a result, the first depth may be a length from the upper surface of the first interlayer insulating layer 105 to the upper surface of the anti-etching layer BL.

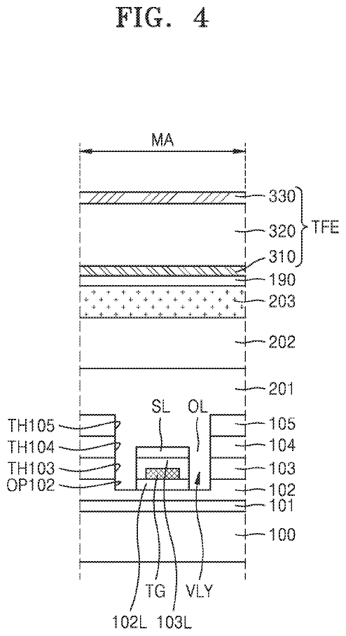

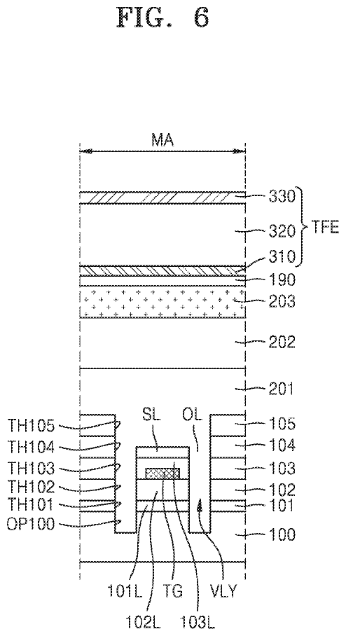

By adjusting conditions of the etching process used (or included) in the forming of the valley structure VLY, the first depth may be adjusted as illustrated in FIGS. 4 and 6 described below.

The forming of the valley structure VLY may further include filling the organic material OL into the valley structure VLY after applying the etching process. The organic material OL that is filled in the valley structure VLY and a material included in the first organic insulating layer 201 may be a same material. The filling of the organic material OL may be performed simultaneously with a forming of the first organic insulating layer 201. For example, the filling of the organic material OL after applying the etching process may include forming the first organic insulating layer 201. However, in another embodiment, the filling of the organic material OL after the applying of the etching process may be performed separately from the forming of the first organic insulating layer 201. As a result, the organic material OL may fill an area having the first depth and an area having the second depth in the valley structure VLY.

For example, after the applying of the etching process included in the forming of the valley structure VLY, the first conductive layer 150 may be formed. After forming the first conductive layer 150, the first organic insulating layer 201 may be formed on the first conductive layer 150. As a result, in the forming of the first organic insulating layer 201, the organic material OL may be filled into the valley structure VLY.

FIG. 4 is a schematic cross-sectional view of the middle area MA of FIG. 3 in accordance with an embodiment. Descriptions of FIG. 4 that are the same as or redundant to the descriptions provided above may be omitted.

As illustrated in FIG. 4, the target TG may be arranged between the first-first insulating portion 102L and the first-second insulating portion 103L, and the first-first insulating portion 102L and a first insulating layer (see, e.g., the buffer layer 102 in FIG. 4) may be arranged on a same layer, and may include a same material. The first-second insulating portion 103L and a second insulating layer (see, e.g., the first gate insulating layer 103 in FIG. 4) may be arranged on a same layer, and may include a same material.

The shield portion SL may be disposed on the first-second insulating portion 103L, and a lower surface of the shield portion SL may contact (e.g., directly contact) an upper surface of the first-second insulating portion 103L. A thickness of the organic material OL covering the shield portion SL in the embodiment of FIG. 4 may be, based on an upper surface of the shield portion SL, greater than the thickness of the organic material OL covering the shield portion SL in the embodiment of FIG. 3.

Unlike the embodiment of FIG. 3, in the embodiment of FIG. 4, the first-third insulating portion 104L may be omitted. Accordingly, the shield portion SL and the first gate layer (see, e.g., 130 in FIG. 3) may be arranged on a same layer, and may include a same material. For example, the shield portion SL may be formed simultaneously with the first gate layer 130 and may constitute a portion of the first gate layer 130.

FIG. 5 is a schematic cross-sectional view of the middle area MA of FIG. 3 in accordance with another embodiment. Descriptions of FIG. 5 that are the same as or redundant to the descriptions provided above may be omitted.

As illustrated in FIG. 5, the target TG may be arranged between the first-first insulating portion 102L and the first-second insulating portion 103L, and the first-first insulating portion 102L and a first insulating layer (see, e.g., the buffer layer 102 in FIG. 5) may be arranged on the same layer, and may include the same material. The first-second insulating portion 103L and a second insulating layer (see, e.g., the first gate insulating layer 103 in FIG. 5) may be arranged on the same layer, and may include the same material.

The shield portion SL may be disposed on the first-second insulating portion 103L, and a lower surface of the shield portion SL may contact (e.g., directly contact) an upper surface of the first-second insulating portion 103L. A thickness of the organic material OL covering the shield portion SL in the embodiment of FIG. 5 may be, based on an upper surface of the shield portion SL, greater than the thickness of the organic material OL covering the shield portion SL in the embodiment of FIG. 3.

Unlike embodiments of FIGS. 3 and 4, in the embodiment of FIG. 5, the anti-etching layer BL may be disposed on the barrier layer 101. In forming the valley structure VLY, the anti-etching layer BL may adjust a depth of the valley structure VLY during an etching process. Because the anti-etching layer BL is disposed on the barrier layer 101, an etching gas may be prevented from reaching the barrier layer 101.

As illustrated in FIG. 5, the first insulating layer may include the opening OP102 filled with the organic material OL, and a lower surface of the opening OP102 may be an upper surface of the anti-etching layer BL.

The anti-etching layer BL and the lower metal layer 110 may be arranged on a same layer, and may include a same material. For example, the anti-etching layer BL and the lower metal layer 110 may be formed in a same process. Accordingly, the anti-etching layer BL and the lower metal layer 110 may have a same layer structure. The expression “two or more layers have a same layer structure” as used herein may mean that the layers include a same material and are formed simultaneously with each other, and the layers have a same structure regardless of whether the layers have a single layer or multiple layers.

During an etching process to form the valley structure VLY, the anti-etching layer BL may prevent etching such that only an intended layer may be etched. As such, by using the anti-etching layer BL during the etching process, etching may be performed to a desired depth. However, the disclosure is not limited thereto, in another embodiment, by controlling a concentration of an etching gas, a composition of the etching gas, and a time of exposure to the etching gas during the etching process, etching may be performed to a desired depth without the anti-etching layer BL.

FIG. 6 is a schematic cross-sectional view of the middle area MA of FIG. 3 in accordance with another embodiment. Descriptions of FIG. 6 that are the same as or redundant to the descriptions provided above may be omitted.

As illustrated in FIG. 6, the target TG may be disposed on the first-first insulating portion 102L and may be arranged between the first-first insulating portion 102L and the first-second insulating portion 103L. A portion 101L of the barrier layer 101 may remain below the target TG and the first-first insulating portion 102L. The portion 101L of the barrier layer 101 may arranged between the substrate 100 and the first-first insulating portion 102L.

The first-first insulating portion 102L and a first insulating layer (see, e.g., the buffer layer 102 in FIG. 6) may be arranged on a same layer, and may include a same material, and the first-second insulating portion 103L and a second insulating layer (see, e.g., the first gate insulating layer 103 in FIG. 6) may be arranged on a same layer, and may include a same material.

The shield portion SL may be disposed on the first-second insulating portion 103L, and a lower surface of the shield portion SL may contact (e.g., directly contact) an upper surface of the first-second insulating portion 103L. A thickness of the organic material OL covering the shield portion SL in the embodiment of FIG. 6 may be, based on an upper surface of the shield portion SL, greater than the thickness of the organic material OL covering the shield portion SL in the embodiment of FIG. 3.

Unlike the embodiments of FIGS. 3 and 4, in the embodiment of FIG. 6, a lower through-hole TH101 may be formed in the barrier layer 101, and another lower through-hole TH102 may be formed in the buffer layer 102. As a result, the valley structure VLY may extend to the substrate 100, and the substrate 100 may further include a lower opening OP100 connected to the lower through-hole TH101 included in the barrier layer 101. As such, the display apparatus or display panel 10 including the valley structure VLY extending to the substrate 100 may have a structure that is more robust against an external impact.

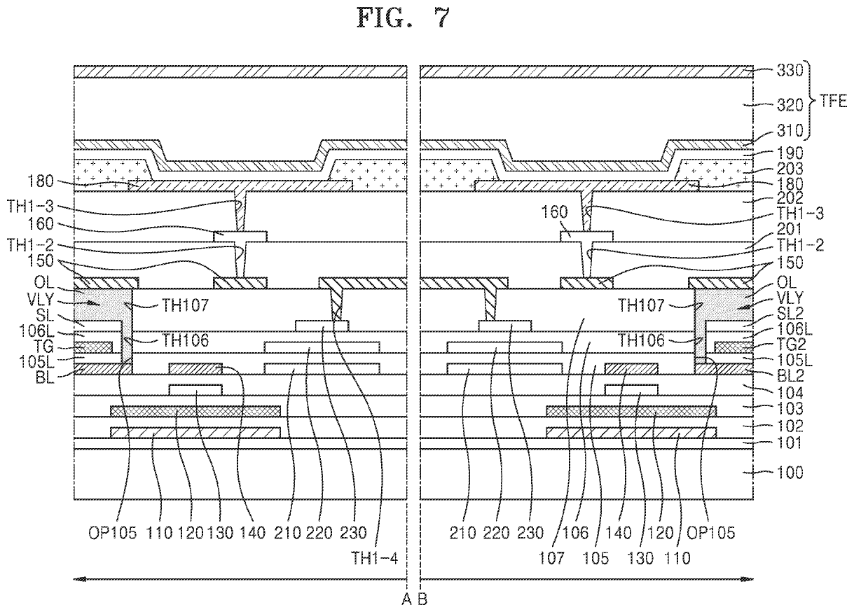

FIG. 7 is a schematic cross-sectional view of a portion of the display panel 10 of FIG. 1 in accordance with another embodiment.

Descriptions of FIG. 7 that are the same as or redundant to the descriptions provided above may be omitted. For convenience of description, FIGS. 3 to 6 and 7 are described as separate embodiments. However, in another embodiment, at least two of structures of FIGS. 3 to 6 and a structure of FIG. 7 may be simultaneously used in the display panel (e.g., an entire area of the display panel) 10.

As illustrated in FIG. 7, the portion of the display panel 10 of FIG. 1 may include area A arranged in a direction and area B arranged in another direction, with respect to the center of the pixel electrodes 180 described below. Because patterns of repeated shapes are used in patterning for implementing an image in the display panel 10, for convenience of description, descriptions of a structure between the area A and the area B are omitted.

In an embodiment, referring to FIG. 7, the area A and the area B may be symmetrical. However, the disclosure is not limited thereto, in another embodiment, structures arranged in the area A and the area B may be different from each other, as in embodiments described below.

In the following descriptions, a stacked structure of the area A is described. Descriptions of the area B in FIG. 7 may be same as descriptions of the area A in FIG. 7. For example, descriptions of a second shield portion SL2, a second target TG2, and a second anti-etching layer BL2 in the area B may be same as the description of the shield portion SL, the target TG, and the anti-etching layer BL in the area A.

The display panel 10 may include the substrate 100, the barrier layer 101, the lower metal layer 110, the buffer layer 102, the first semiconductor layer 120, the first gate insulating layer 103, the first gate layer 130, the second gate insulating layer 104, the second gate layer 140, and the first interlayer insulating layer 105. Descriptions of the above components are the same as or redundant to the descriptions provided with reference to FIG. 3 or the like and are thus omitted.

As illustrated in FIG. 7, the display panel 10 may further include a second semiconductor layer 220 disposed on the first interlayer insulating layer 105. The second semiconductor layer 220 may be arranged between the first interlayer insulating layer 105 and a third gate insulating layer 106 and may include SiO₂. The second semiconductor layer 220 may include a channel area not doped with impurities and a source area at a side of the channel area and a drain area at another side of the channel area that are doped with impurities. The impurities may vary according to a type of a thin-film transistor and may be N-type impurities or P-type impurities. Because an oxide semiconductor is readily affected by electromagnetic waves introduced from an outside, an additional lower metal layer 210 may be further disposed below the second semiconductor layer 220. The additional lower metal layer 210 may be arranged between the second gate insulating layer 104 and the first interlayer insulating layer 105.

The additional lower metal layer 210 may be disposed on the first gate insulating layer 103. The additional lower metal layer 210 and the second gate layer 140 may be arranged on a same layer. The additional lower metal layer 210 and the second gate layer 140 may include a same material. The additional lower metal layer 210 and the second gate layer 140 may have a same layer structure. The additional lower metal layer 210 may be formed simultaneously with the second gate layer 140 and may constitute a portion of the second gate layer 140.

In a plan view, the additional lower metal layer 210 may overlap the second semiconductor layer 220, and an area of the additional lower metal layer 210 may be greater than an area of the second semiconductor layer 220. In a bottom view, at least a portion of the second semiconductor layer 220 may be covered by the additional lower metal layer 210.

The third gate insulating layer 106 may be disposed on the second semiconductor layer 220. The third gate insulating layer 106 may secure insulation between the second semiconductor layer 220 and a third gate layer 230 described below. The third gate insulating layer 106 may include an inorganic material, such as SiO₂, SiNₓ, SiON, the like, or a combination thereof, and may be arranged between the second semiconductor layer 220 and the third gate layer 230 described below. The third gate insulating layer 106 may have a structure in which contact holes are formed in parts (e.g., preset parts). The third gate insulating layer 106 may include an inorganic material and may be formed through CVD, ALD, or the like. This may also apply to embodiments described below and modifications thereof.

The third gate layer 230 may be disposed on the third gate insulating layer 106. The third gate layer 230 may be disposed at a position vertically overlapping the second semiconductor layer 220 and may include a metal such as Mo, Al, Pt, Pd, Ag, Mg, Au, Ni, Nd, Ir, Cr, Li, Ca, Ti, W, Cu, and a combination thereof.

At least a portion of the third gate layer 230 may overlap the second semiconductor layer 220 in a plan view. Conversely, at least a portion of the second semiconductor layer 220 may overlap the third gate layer 230 in a plan view.

A second interlayer insulating layer 107 may be disposed on the third gate layer 230. The second interlayer insulating layer 107 may cover the third gate layer 230. The second interlayer insulating layer 107 may include an inorganic material. For example, the second interlayer insulating layer 107 may include a metal oxide or a metal nitride, for example, the second interlayer insulating layer 107 may include SiO₂, SiNₓ, SION, Al₂O₃, TiO₂, Ta₂O₅, HfO₂, ZnO₂, the like, or a combination thereof. In embodiments, the second interlayer insulating layer 107 may have a dual structure of SiOₓ/SiN_{y} or SiNₓ/SiO_{y}.

As illustrated in FIG. 7, the first conductive layer 150 may be disposed on the second interlayer insulating layer 107. The first conductive layer 150 may serve as an electrode electrically connected to the source or drain area of the second semiconductor layer 220 through a through-hole included in the second interlayer insulating layer 107. The first conductive layer 150 may be electrically connected to the third gate layer 230 through a first-fourth contact hole TH1-4. The first conductive layer 150 may cover at least a portion of an upper surface of the valley structure VLY. Other descriptions of the first conductive layer 150 are the same as or redundant to the descriptions provided with reference to FIG. 3 or the like and are thus omitted.

The first organic insulating layer 201 may be disposed on the first conductive layer 150, and the second conductive layer 160 may be disposed on the first organic insulating layer 201. The second organic insulating layer 202 may be disposed on the second conductive layer 160. The pixel electrode 180 may be disposed on the second organic insulating layer 202, and the pixel-defining layer 203 may be disposed on the second organic insulating layer 202 and may cover an edge of the pixel electrode 180. An intermediate layer (not illustrated) and the counter electrode 190 may be disposed on the pixel electrode 180 and the pixel-defining layer 203, and the thin-film encapsulation layer TFE may be disposed on the intermediate layer (not illustrated) and the counter electrode 190. Descriptions of the first organic insulating layer 201, the first conductive layer 150, the second organic insulating layer 202, the pixel electrode 180, the intermediate layer (not illustrated), the counter electrode 190, the pixel electrode 180, and the thin-film encapsulation layer TFE are the same as or redundant to the descriptions provided with reference to FIG. 3 or the like and are thus omitted.

Although not illustrated in FIG. 7, an additional conductive layer and an additional insulating layer may be arranged between a conductive layer (e.g., the first conductive layer 150 and the second conductive layer 160) described above and the pixel electrode 180 described below, but the disclosure is not limited thereto.

As illustrated in FIG. 7, the valley structure VLY arranged in the area A of the display panel 10 and the valley structure VLY arranged in FIGS. 3 to 6 may be arranged at different positions in a cross-sectional view. In the following descriptions, the area A is described in detail.

The first interlayer insulating layer 105 may include an opening OP105 filled with the organic material OL. A second-first insulating portion 105L may be arranged inside the opening OP105 of the first interlayer insulating layer 105. For example, the first interlayer insulating layer 105 may include the second-first insulating portion 105L arranged inside the opening OP105. The second-first insulating portion 105L and the first interlayer insulating layer 105 may be arranged on a same layer, and may include a same material. The second-first insulating portion 105L and the first interlayer insulating layer 105 may have a same layer structure. The second-first insulating portion 105L and the first interlayer insulating layer 105 may be formed in a same process.

The third gate insulating layer 106 may include a second-first through-hole TH106 filled with the organic material OL and connected to the opening OP105 included in the first interlayer insulating layer 105. A second-second insulating portion 106L may be arranged inside the second-first through-hole TH106. For example, the third gate insulating layer 106 may include the second-second insulating portion 106L arranged inside the second-first through-hole TH106. The second-second insulating portion 106L and the third gate insulating layer 106 may be arranged on a same layer, and may include a same material. The second-second insulating portion 106L and the second interlayer insulating layer 107 may have a same layer structure. The second-second insulating portion 106L and the third gate insulating layer 106 may be formed in a same process. At least a portion of a lower surface of the second-second insulating portion 106L may contact an upper surface of the second-first insulating portion 105L. The target TG may be arranged between the second-first insulating portion 105L and the second-second insulating portion 106L.

The second interlayer insulating layer 107 may include a second-second through-hole TH107 filled with the organic material OL and connected to the second-first through-hole TH106. The shield portion SL may be arranged inside the second-second through-hole TH107. For example, the second interlayer insulating layer 107 may include the shield portion SL arranged inside the second-second through-hole TH107. The shield portion SL may be disposed on the second interlayer insulating layer 107. The shield portion SL and the third gate layer 230 may be arranged on a same layer, and may include a same material. The shield portion SL and the third gate layer 230 may have a same layer structure. The shield portion SL and the third gate layer 230 may be formed in a same process. At least a portion of a lower surface of the shield portion SL may contact the upper surface of the second-first insulating portion 105L.

The opening OP105 of the first interlayer insulating layer 105, the second-first through-hole TH106, and the second-second through-hole TH107 may be connected to each other. For example, an inner surface of the opening OP105 of the first interlayer insulating layer 105, an inner surface of the second-first through-hole TH106, and an inner surface of the second-second through-hole TH107 may form (or constitute) a continuous surface with each other.

Unlike the illustrations of FIGS. 3 to 6, the target TG of FIG. 7 and the second semiconductor layer 220 may be arranged on a same layer. For example, the target TG may be arranged inside the valley structure VLY, may be disposed on the second-first insulating portion 105L, and may be covered by the second-second insulating portion 106L. Side and upper surfaces of the target TG may be covered by the second-second insulating portion 106L. The target TG may be a portion of the second semiconductor layer 220 that is formed by dopant implantation or the like to serve as a wiring.

The target TG described herein, which is a layer arranged inside the valley structure VLY, may be a layer that performs a function (e.g., a specific function) in the display apparatus or display panel 10, such as a wiring or the like, and needs to be protected from an etching gas used in an etching process.

The shield portion SL for protecting the target TG from an etching gas may be disposed on the target TG. For example, the shield portion SL may be disposed on the second-second insulating portion 106L covering the target TG. In a plan view, the shield portion SL may cover the target TG. In a plan view, the shield portion SL may overlap the target TG. For example, in a plan view, an area of the shield portion SL may be greater than an area of the target TG, and the shield portion SL may protect the target TG from an etching gas. Accordingly, a material included in the shield portion SL may be a material having a lower etching rate than a material to be etched (see, e.g., the target TG or the insulating layers described above (e.g., the first interlayer insulating layer 105, the third insulating layer 106, the second interlayer insulating layer 107) in FIG. 7). The shield portion SL may be disposed on the target TG. The shield portion SL and the third gate layer 230 may include a same material such as a metal having a relatively low etching rate, and may be formed simultaneously with each other.

For example, in a plan view, the shield portion SL may cover the second-first insulating portion 105L and the second-second insulating portion 106L. The shield portion SL may cover an upper surface of the second-second insulating portion 106L and may contact (e.g., directly contact) the upper surface of the second-second insulating portion 106L. For example, the shield portion SL may prevent the second-first insulating portion 105L, the second-second insulating portion 106L, and the target TG from being etched.

Unlike the illustrations of FIGS. 3 to 6, for example, the anti-etching layer BL and the second gate layer 140 may be arranged on a same layer. The anti-etching layer BL and the second gate layer 140 may include a same material. The anti-etching layer BL and the second gate layer 140 may have a same layer structure. The anti-etching layer BL and the second gate layer 140 may be formed in a same process. A lower surface of the opening OP105 formed in the first interlayer insulating layer 105 may include at least a portion of an upper surface of the anti-etching layer BL.

A process for forming a display apparatus or display panel 10 including the valley structure VLY as illustrated in FIG. 7 (hereinafter, a manufacturing method) may be as follows.

The manufacturing method may include sequentially forming the barrier layer 101, the lower metal layer 110, the buffer layer 102, the first semiconductor layer 120, the first gate insulating layer 103, the first gate layer 130, the second gate insulating layer 104, the second gate layer 140, the first interlayer insulating layer 105, the second semiconductor layer 220, the third gate insulating layer 106, the third gate layer 230, and the second interlayer insulating layer 107 (hereinafter, sequential forming). In another embodiment, at least one of the barrier layer 101, the lower metal layer 110, and the second gate layer 140 may be omitted. The sequential forming may be applied by using a process.

For example, the sequential forming may include forming the anti-etching layer BL. Because the anti-etching layer BL is formed simultaneously with the third gate layer 230, the forming of the anti-etching layer BL may be sequentially forming the third gate layer 230 after forming the third gate insulating layer 106.

The manufacturing method may further include forming the valley structure VLY after the sequential forming. The forming of the valley structure VLY may include, for example, forming the valley structure VLY in the area A and/or the area B of FIG. 7. The forming of the valley structure VLY may include, for example, forming the valley structure VLY in an area (e.g., a preset area) in the area A and/or the area B of FIG. 7.

The area for the forming of the valley structure VLY in FIG. 7 may be defined adjacent to an area in which the shield portion SL is arranged in the area A and/or the area B. For example, the area for the forming of the valley structure VLY may be an area in which the shield portion SL is arranged in the area A and/or the area B in a plan view.

Accordingly, the forming of the valley structure VLY may include removing an insulating material disposed on the shield portion SL in the area in which the shield portion SL is arranged and removing the insulating material to a depth (e.g., a preset depth) in a remaining area in which the shield portion SL is not arranged. For example, as illustrated in FIG. 7, the valley structure VLY may extend to the upper surface of the anti-etching layer BL.

As a result, the valley structure VLY may have a third depth from an upper surface of the second interlayer insulating layer 107 to the upper surface of the anti-etching layer BL and may have a fourth depth from the upper surface of the second interlayer insulating layer 107 to an upper surface of the shield portion SL. The third depth may be greater than the fourth depth.

Accordingly, a buffering effect against an external impact may be achieved by a portion of the valley structure VLY having the third depth. Accordingly, the valley structure VLY described herein may not only have the buffering effect against an external impact, but also may protect the target TG serving as a wiring or the like from an etching process. Accordingly, the valley structure VLY described herein may be freely arranged within the display area DA of the display apparatus and may provide a greater degree of freedom in designing a display circuit structure including the valley structure VLY.

Furthermore, the valley structure VLY described herein may also have a buffering effect against an external impact through an organic material having the fourth depth, thereby protecting the target TG from the external impact.

An etching process used (or included) in the forming of the valley structure VLY in FIG. 7 and an etching process used (or included) in the forming of the first-fourth contact hole TH1-4 may be the same. As described above, the first-fourth contact hole TH1-4 may electrically connect the first conductive layer 150 to the third gate layer 230.

The forming of the valley structure VLY in FIG. 7 may further include filling the organic material OL into the valley structure VLY after applying the etching process. The organic material OL that is filled in the valley structure VLY and a material included in the first organic insulating layer 201 may be a same material. The filling of the organic material OL may be performed simultaneously with a forming the first organic insulating layer 201. For example, the filling of the organic material OL after the applying of the etching process may include the forming of the first organic insulating layer 201. However, in another embodiment, the filling of the organic material OL after the applying of the etching process may be performed separately from the forming of the first organic insulating layer 201. As a result, the organic material OL may fill an area having the third depth in the valley structure VLY of FIG. 7 and may fill an area having the fourth depth in the valley structure VLY of FIG. 7.

For example, after the applying of the etching process included in the forming of the valley structure VLY, the first conductive layer 150 may be formed. After forming the first conductive layer 150, the first organic insulating layer 201 may be formed on the first conductive layer 150. As a result, in the forming of the first organic insulating layer 201, the organic material OL may be filled into the valley structure VLY.

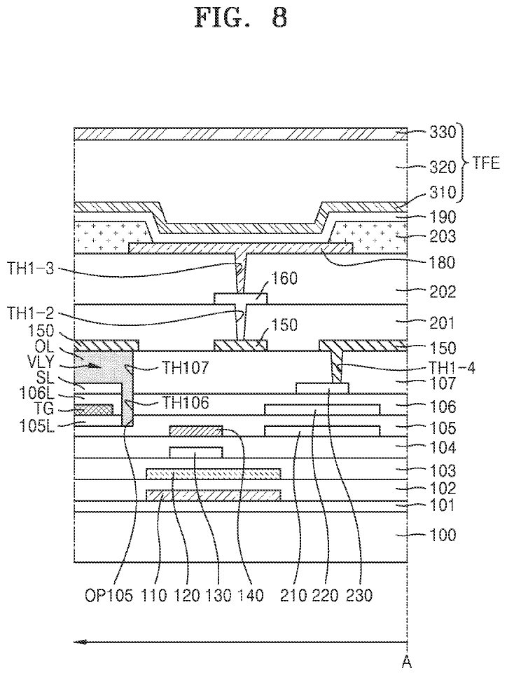

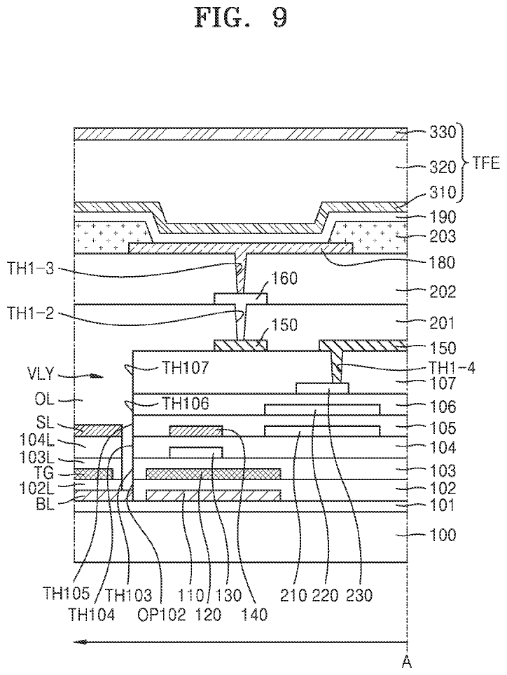

FIG. 8 is a schematic cross-sectional view of the area A of FIG. 7 in accordance with another embodiment, and FIG. 9 is a schematic cross-sectional view of the area A of FIG. 7 in accordance with another embodiment.

Descriptions of FIGS. 8 and 9 that are the same as or redundant to the descriptions provided above may be omitted.

As illustrated in FIG. 8, in an embodiment, the anti-etching layer BL of FIG. 7 may be omitted. Accordingly, in an etching process for forming the valley structure VLY, the depth of the valley structure VLY may be adjusted by adjusting an exposure time to an etching gas, a concentration of the etching gas, a composition of the etching gas, or the like.

Accordingly, unlike the third depth described above with reference to FIG. 7, the third depth of the valley structure VLY in FIG. 8 may be a depth from an upper surface of the second interlayer insulating layer 107 to a bottom surface of the opening OP105 formed in the first interlayer insulating layer 105.

As illustrated in FIG. 9, the target TG and the first semiconductor layer 120 may be arranged on a same layer. The valley structure VLY may extend from the second interlayer insulating layer 107 to the opening OP102 formed in the buffer layer 102, as in embodiments of FIGS. 3 to 6. The shield portion SL and the second gate layer 140 may be arranged on a same layer, and may include a same material.

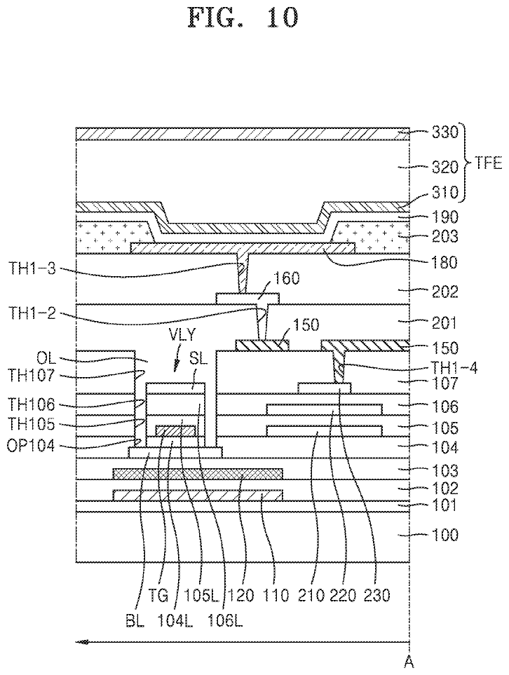

FIG. 10 is a schematic cross-sectional view of a portion of the display panel 10 of FIG. 1 in accordance with another embodiment.

Descriptions of FIG. 10 that are the same as or redundant to the descriptions provided above may be omitted. For convenience of description, FIGS. 3 to 10 are described as separate embodiments. However, in another embodiment, at least two of the structures of FIGS. 3 to 10 may be simultaneously used in the display panel (e.g., an entire area of the display panel) 10.

As illustrated in FIG. 10, the target TG may include a structure other than the first semiconductor layer 120 and the second semiconductor layer 220. This is because a position at which the valley structure VLY is formed may be variously modified.

Although FIG. 10 illustrates that the target TG and the additional lower metal layer 210 are arranged on a same layer, the disclosure is not limited thereto, and in another embodiment, the target TG and the first gate layer 130 or the second gate layer 140 may be arranged on a same layer, and may be variously modified.

For example, in case that the target TG and the additional lower metal layer 210 are arranged on a same layer, and include a same material, the shield portion SL may be disposed on the target TG. The shield portion SL and the third gate layer 230 may be arranged on a same layer, and may include a same material. The third gate layer 230 may be disposed on the additional lower metal layer 210. As such, according to a position of the target TG, the valley structure VLY may be applied in various ways.

For example, in case that the target TG and the additional lower metal layer 210 are arranged on a same layer, the first gate layer 130 may function as the anti-etching layer BL to prevent a thin-film transistor from being damaged due to excessive etching. A lower surface of an opening OP104 formed in the second gate insulating layer 104 may include at least a portion of an upper surface of the first gate layer 130.

According to the embodiments described above, a display apparatus that is more robust against an external impact may be implemented. However, the scope of the disclosure is not limited by this effect.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a first insulating layer disposed on a substrate and comprising:
an opening filled with an organic material; and
a first-first insulating portion arranged inside the opening;
a second insulating layer disposed on the first insulating layer and comprising:
a first-first through-hole filled with the organic material and connected to the opening; and
a first-second insulating portion arranged inside the first-first through-hole;
a third insulating layer disposed on the second insulating layer and comprising a first-second through-hole filled with the organic material and connected to the first-first through-hole;
a target arranged between the first-first insulating portion and the first-second insulating portion and arranged inside the first-first through-hole; and
a shield portion disposed on the second insulating layer or the third insulating layer and overlapping the target in a plan view.

2. The display apparatus of claim 1, further comprising:
an anti-etching layer arranged between the substrate and the first insulating layer,
wherein a lower surface of the opening comprises at least a portion of an upper surface of the anti-etching layer.

3. The display apparatus of claim 1, wherein, in a plan view, at least a portion of the target is covered by the shield portion.

4. The display apparatus of claim 1, wherein, in a plan view, an area of the target is less than an area of the shield portion.

5. The display apparatus of claim 2, further comprising:
a first semiconductor layer, and
wherein the first semiconductor layer and the target are arranged on a same layer and comprise a same material.

6. The display apparatus of claim 1, wherein an inner surface of the opening, an inner surface of the first-first through-hole, and an inner surface of the first-second through-hole constitute a continuous surface with each other.

7. The display apparatus of claim 1, wherein a side surface and an upper surface of the target are covered by the first-second insulating portion.

8. The display apparatus of claim 5, further comprising:
a first gate layer disposed on the first semiconductor layer and spaced apart from the first semiconductor layer; and
a second gate layer disposed on the first gate layer and spaced apart from the first gate layer.

9. The display apparatus of claim 8, wherein the shield portion and the second gate layer are arranged on a same layer and comprise a same material.

10. The display apparatus of claim 1, further comprising:
a fourth insulating layer disposed on the third insulating layer and comprising a first-third through-hole filled with the organic material and connected to the first-second through-hole.

11. The display apparatus of claim 10, wherein
the third insulating layer comprises a first-third insulating portion arranged inside the first-second through-hole, and
the shield portion is disposed on the first-third insulating portion and arranged inside the first-third through-hole.

12. The display apparatus of claim 11, wherein a side surface and an upper surface of the shield portion are covered by the organic material.

13. A display apparatus comprising:
a first semiconductor layer disposed on a substrate;
a first gate insulating layer disposed on the first semiconductor layer;
a first gate layer disposed on the first gate insulating layer;
a second gate insulating layer disposed on the first gate layer;
a second gate layer disposed on the second gate insulating layer;
a first interlayer insulating layer disposed on the second gate layer and comprising:
an opening filled with an organic material; and
a second-first insulating portion arranged inside the opening;
a third gate insulating layer disposed on the first interlayer insulating layer and comprising:
a second-first through-hole filled with the organic material and connected to the opening; and
a second-second insulating portion arranged inside the second-first through-hole;
a second interlayer insulating layer disposed on the third gate insulating layer and comprising a second-second through-hole filled with the organic material and connected to the second-first through-hole;
a target arranged between the second-first insulating portion and the second-second insulating portion and arranged inside the second-first through-hole; and
a shield portion disposed on the third gate insulating layer and overlapping the target in a plan view.

14. The display apparatus of claim 13, further comprising:
an anti-etching layer arranged between the second gate insulating layer and the first interlayer insulating layer,
wherein a lower surface of the opening comprises at least a portion of an upper surface of the anti-etching layer.

15. The display apparatus of claim 13, wherein, in a plan view, at least a portion of the target is covered by the shield portion.

16. The display apparatus of claim 13, wherein, in a plan view, an area of the target is less than an area of the shield portion.

17. The display apparatus of claim 13, further comprising:
a second semiconductor layer,
wherein the second semiconductor and the target are arranged on a same layer and comprise a same material.

18. The display apparatus of claim 17, wherein the second semiconductor layer comprises an oxide semiconductor.

19. The display apparatus of claim 13, wherein an inner surface of the opening, an inner surface of the second-first through-hole, and an inner surface of the second-second through-hole constitute a continuous surface with each other.

20. The display apparatus of claim 13, wherein a side surface and an upper surface of the target are covered by the second-second insulating portion.
